(19) United States
(12) Patent Application Publication
(10) Pub. No.: US 2014/0061070 A1
(43) Pub. Date: Mar. 6, 2014

(54) METHOD FOR MANUFACTURING A CASE FOR A PORTABLE ELECTRONIC DEVICE, AND CASE FOR A PORTABLE ELECTRONIC DEVICE

(71) Applicant: Jeong Kee Seok, Incheon (KR)

(72) Inventor: Jeong Kee Seok, Incheon (KR)

(73) Assignee: INMOK CO., LTD., Incheon (KR)

(21) Appl. No.: 14/114,607

(22) PCT Filed: Aug. 24, 2012
(86) PCT No.: PCT/KR2012/006760

§ 371 Date: Oct. 29, 2013

(30) Foreign Application Priority Data
Sep. 1, 2011 (KR) 10-2011-0088555

(51) Int. Cl. A45C 11/00; H05K 13/00

(52) U.S. Cl. CPC A45C 11/00; H05K 13/00
USPC 206/37; 156/245

(57) ABSTRACT

Provided is a method for manufacturing a case for a portable electronic device. The method includes: adhesive applying for applying an adhesive to a back side of a sliced veneer sheet; reinforcing strengthener attaching for attaching a reinforcing strengthener, which has a higher tensile and rupture strength than the sliced veneer sheet, to the back side of the sliced veneer sheet, so as to reinforce a strength of a sliced veneer; elastic layer forming for providing an elastic layer, which is made of a more elastic material than the sliced veneer sheet, to a surface of the reinforcing strengthener so as to provide elasticity to the sliced veneer sheet; and injection molding for injection-molding a case body that is formed of a synthetic resin material to cover at least one side of the portable electronic device, by inserting the sliced veneer sheet, the reinforcing strengthener, and the elastic layer into a mold.

### TECHNICAL FIELD

One or more aspects of the present invention relate to a method for manufacturing a case for a portable electronic device, and case for a portable electronic device, and more particularly, to a method for manufacturing a case for a portable electronic device for preventing stripping, a shake, or deformation of a sliced veneer in the case that is manufactured by using a sliced veneer, and the portable electronic device.

### BACKGROUND ART

Recently, as advancements in electronic technologies have lead to widespread use of a portable electronic device, most people use a portable electronic device such as a cellular phone, a moving pictures expert group audio layer 3 (MP3), a portable media player (PMP) or a high-end touch-screen cellular phone that provides a wireless internet access.

Since the portable electronic device is formed of synthetic resin or glass that may be easily scratched, most people put a portable electronic device in a case, to carry and use the portable electronic device.

A case for a portable electronic device was formed solely of a synthetic material or manufactured by applying a certain paint to metal. However, since the case, which is formed of a synthetic material or manufactured by applying a certain paint to a surface of the case, has an artificial feel, people may get easily tired of such a case. Additionally, such a case may react sensitively to an external temperature, and thus, may have a cold feel.

Recently, a case, which is manufactured by attaching a wooden material such as a sliced veneer to a side of the case, is disclosed in Korean Patent Publication No. 10-2008-0024713. As such, a case, which is manufactured by attaching a sliced veneer to a side of a case, has a natural feel and may not sensitively react to an external temperature due to properties of a wood material. Thus, a cold feel in the case may be reduced and aesthetic feel, which may not be artificially expressed, may be psychologically created. However, it is difficult to adhere a sliced veneer, obtained by cutting wood, to a non-homogeneous material such as plastic or metal. Even after the sliced veneer is adhered to the non-homogeneous material, the sliced veneer may be deformed due to different material properties from each other. Additionally, a sliced veneer, with a thick thickness, may easily split in a grain direction, and a sliced veneer, with a thin thickness, may be easily broken or its surface may be cracked due to its weak compression, tensile, or rupture strength. The sliced veneer has a high absorbency for absorbing moisture. Thus, when absorbing moisture, the sliced veneer linearly and volumetrically expands. On the contrary, when losing moisture, the sliced veneer linearly and volumetrically contracts. If heat is applied to the sliced veneer, the sliced veneer also linearly and volumetrically expands even though far less than when absorbing moisture. On the contrary, when losing heat, the sliced veneer linearly and volumetrically contracts. Also, the sliced veneer has an unstable size and different ratios of expansion and contraction according to directions of the sliced veneer, and thus, may be irregularly deformed, bent, or twisted. This is due to anisotropy of wood, that is, different material properties like a ratio of expansion and contraction according to moisture or heat, depending on directions such as a fiber direction, a tangential direction, and a radial direction. Even when the sliced veneer is painted, its expansion or contraction, which may be caused by incoming and outgoing moisture or heat, may not completely removed unless incoming and outgoing of moisture is completely prevented.

### DETAILED DESCRIPTION OF THE INVENTION

### Technical Problem

In order to solve the problems, described above, one or more aspects of the present invention provide a method for manufacturing a case for a portable electronic device for preventing a sliced veneer, which is attached to a case body, from stripping off from the case body or being deformed due to an external shock, or expansion or contraction caused by moisture or heat, and preventing deformation of the case of the portable electronic device by stabilizing a size of the sliced veneer that is attached to a non-homogeneous material such as plastic, and the case for the portable electronic device.

### Technical Solution

According to an aspect of the present invention, there is provided a method for manufacturing a case for a portable electronic device, the method including: adhesive applying for applying an adhesive to a back side of a sliced veneer sheet; reinforcing strengthener attaching for attaching a reinforcing strengthener, which has a higher tensile and rupture strength than the sliced veneer sheet, to the back side of the sliced veneer sheet, so as to reinforce a strength of a sliced veneer; elastic layer forming for providing an elastic layer, which is made of a more elastic material than the sliced veneer sheet, to a surface of the reinforcing strengthener so as to provide elasticity to the sliced veneer sheet; and injection molding for injection-molding a case body that is formed of a synthetic resin material to cover at least one side of the portable electronic device, by inserting the sliced veneer sheet, the reinforcing strengthener, and the elastic layer into a mold.

The method may further include, between the elastic layer forming and the injection molding, surface polishing for polishing a surface of the sliced veneer sheet and, at the same time, softening a structure in the sliced veneer by using a certain polishing element.

The elastic layer forming may include: applying of an elastic material to a surface of the reinforcing strengthener; attaching a film to the surface of the elastic material; uniforming a thickness of the elastic material by pressing an entire surface of the film; and removing the film.

The method may further include, between the elastic layer forming and the injection molding, waterproofing and surface protecting layer forming for forming a waterproofing and surface protecting layer on a surface of the sliced veneer sheet, so as to maintain waterproofing performance at and protect the surface of the sliced veneer sheet.

The waterproofing and surface protecting layer forming may be performed when, in such a state that a waterproofing and surface protecting sheet is formed to face the sliced veneer sheet and inserted together with the sliced veneer sheet into the mold, the waterproofing and surface protecting sheet melts or remains in a process of the injection molding, and thus, the waterproofing and surface protecting layer is formed on a surface of the sliced veneer sheet.

The reinforcing strengthener may be formed of a material that has a higher melting point than a synthetic resin material, which forms the case body, and prevents a synthetic resin material in a melting state from penetrating into the sliced veneer sheet in a process of the injection molding, wherein the reinforcing strengthener is formed of non-woven fabric or other clothes.

The elastic layer may be formed of one from among polyvinyl acetate, polyurethane, rubber and silicon.

According to an aspect of the present invention, there is provided a case of a portable electronic device, the case including: a sliced veneer sheet; a reinforcing strengthener, which has a higher tensile and rupture strength than the sliced veneer sheet, a the back side of the sliced veneer sheet, so as to reinforce a strength of the sliced veneer sheet; an elastic layer, which is made of a more elastic material than the sliced veneer sheet and formed on a surface of the reinforcing strengthener, so as to provide elasticity to the sliced veneer sheet; and a case body formed of a synthetic material, which is injection-molded by inserting the sliced veneer sheet, the reinforcing strengthener, and the elastic layer into the mold, wherein the case body is detachably attached to the portable electronic device to support the sliced veneer sheet, the reinforcing strengthener, and the elastic layer and have a form to cover at least one side of the portable electronic device.

The reinforcing strengthener may be formed of a material that has a higher melting point than a synthetic resin material, which forms the case body, wherein the reinforcing strengthener is formed of non-woven fabric or other clothes.

The elastic layer may be formed of one from among polyvinyl acetate, polyurethane, rubber and silicon.

A waterproofing and surface protecting layer may be formed on a surface of the sliced veneer sheet, so as to maintain waterproofing performance and protect the surface of the sliced veneer sheet.

### ADVANTAGEOUS EFFECTS

According to an embodiment of the present invention, a case for a portable electronic device is provided with a reinforcing strengthener for reinforcing a strength on a back side of a sliced veneer sheet and reducing or removing anisotropy of wood (sliced veneer), and an elastic layer for providing elasticity to the case. Thus, stripping, deformation, or damage of the sliced veneer sheet may be prevented, and splitting or stripping of the sliced veneer in a grain direction may also be prevented due to linear and volumetric expansion of the sliced veneer, which may be caused by external moisture or heat. Additionally, a case for the portable electronic device, of which manufacture is finished, may be prevented from being deformed by a change in an external environment such as a temperature or a humidity.

### DESCRIPTION OF THE DRAWINGS

FIG. 1 is a perspective view of a portable electronic device case according to an embodiment of the present invention;

FIG. 2 is a cross-sectional view of the portable electronic device case taken along line II-II of FIG. 1;

FIG. 3A through 3F are a diagram for illustrating a process of manufacturing the portable electronic device case of FIG. 1;

FIG. 4 is a cross-sectional view of a portable electronic device case according to another embodiment of the present invention;

FIG. 5 is a block diagram illustrating an embodiment of manufacturing the portable electronic device case of FIG. 1 or 4; and

FIG. 6 is a block diagram illustrating another embodiment of manufacturing the portable electronic device case of FIG. 1.

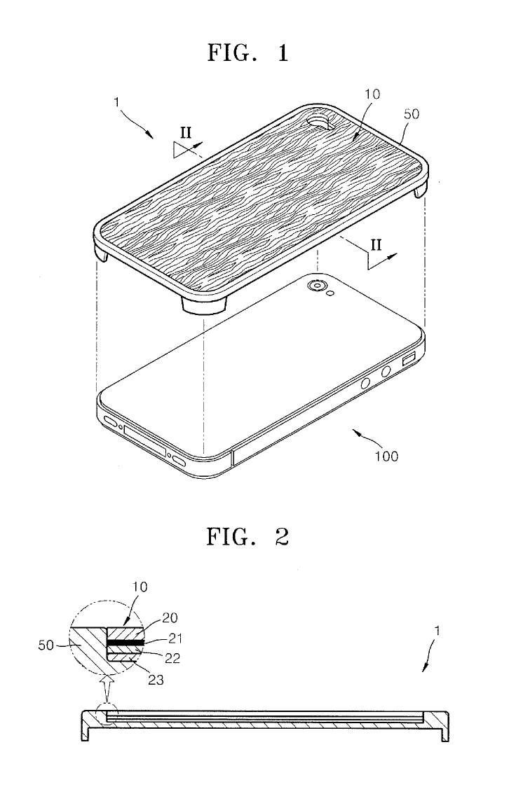

### MODE OF THE INVENTION

Hereinafter, according to an embodiment of the present invention, a portable electronic device case 1 will be described in detail with reference to the attached drawings.

The portable electronic device case 1, in the present invention, refers to a case for protecting an external surface of a portable electronic device 100 such as a cellular phone, a portable multimedia player (PMP), or a moving picture experts audio layer-3 (MP3). The portable electronic device case 1 may have an aesthetic and natural feel by attaching a sliced veneer to the portable electronic device case 1.

The portable electronic device case 1 is formed of a sliced veneer assembly 10 and a case body 50. The sliced veneer assembly 10 is formed to include a sliced veneer sheet 20, a reinforcing strengthener 22, and an elastic layer 23.

The sliced veneer sheet 20 is formed in the form of a thin sheet, and in detail, formed to have a thickness of 0.1 to 0.5 mm to be attached to the case body 50 as one body. A shape of the sliced veneer sheet 20 may be determined according to a shape of a portable electronic device. In the current embodiment, the sliced veneer sheet 20 is formed to have a rectangular surface shape. A sliced veneer, used for the sliced veneer sheet 20, may be a natural veneer, a dyed veneer that is obtained by dyeing a natural veneer, a reconstituted veneer that is obtained by laminating, and then, cutting a veneer, or the like.

The reinforcing strengthener 22 has a higher tensile and rupture strength than the sliced veneer sheet 20, so as to reinforce a strength of a sliced veneer on a back side of the sliced veneer sheet 20. The reinforcing strengthener 22 may be attached to the back side of the sliced veneer sheet 20 by using a certain adhesive 21. The reinforcing strengthener 22 is to reinforce a strength of a sliced veneer, while maintaining a flexibility of the sliced veneer. Especially when attached to the back side of the sliced veneer sheet 20, the reinforcing strengthener 22 may prevent the sliced veneer sheet 20 from contracting, expanding, or splitting in a grain direction due to an external condition. The reinforcing strengthener 22 may be formed of non-woven fabric or other clothes, but is not limited thereto. Various materials may be used as the reinforcing strengthener 22 as necessary.

Additionally, later in a process of injection molding, while a synthetic resin material in a high-temperature melting state is filled in a mold 40, the reinforcing strengthener 22 may function to prevent the synthetic resin material in a high-temperature melting state from penetrating into the sliced veneer through a back side of the sliced veneer. Therefore, the reinforcing strengthener 22 may have a compact structure in which a melting point is higher than a synthetic resin that forms the case body 50. The reinforcing strengthener 22, which has such a structure, may prevent the synthetic resin material from penetrating into the sliced veneer in a process of injection molding, and thus, prevent a split or a rupture in the sliced veneer.

The elastic layer 23 is made of a more elastic material than the sliced veneer sheet 20 on a surface of the sliced veneer sheet 20, so as to provide elasticity to the sliced veneer sheet 20.

The elastic layer 23 may be formed on a surface of the reinforcing strengthener 22 by spraying or applying polyvinyl acetate, polyurethane, rubber or silicon. The elastic layer 23 is attached to the case body 50 while the sliced veneer sheet 20 is being inserted and injected into the mold 40, or after the sliced veneer is attached to the case body 50 after being inserted and injected into the mold 40. The elastic layer 23 is formed to have such a ratio of expansion and contraction that the elastic layer 23 may expand when the sliced veneer sheet 20 expands at a curved surface, a groove, or an edge at which a surface faces another surface of the case body 50, so as to splitting of the sliced veneer sheet, and may reinforce an adhesive force between the sliced veneer sheet 20 and the case body 50, so as to prevent the sliced veneer sheet 20 from being detached from the case body 50.

If an external shock is exerted on the sliced veneer sheet 20, the elastic layer 23 may absorb the external shock. Additionally, if the portable electronic device case 1 is bent, the elastic layer 23 may elastically protect the sliced veneer sheet 20, thus preventing the sliced veneer sheet 20 from being damaged or cracked.

The case body 50 is injection-molded by inserting the sliced veneer sheet 20, the reinforcing strengthener 22, and the elastic layer 23 into the mold 40. The case body 50 may be detachably attached to the portable electronic device 100 so as to support the sliced veneer sheet 20, the reinforcing strengthener 22, and the elastic layer 23, and cover at least one side of the portable electronic device 100. The case body 50 is overall formed to have a shape that corresponds to one side of the portable electronic device 100. Each edge of the case body 50 includes a support unit that protrudes in a lower direction, so that the case body 50 may be detachably attached to the portable electronic device 100 by using the support unit. A receiving groove, which may receive and support the sliced veneer sheet 20, the reinforcing strengthener 22, and the elastic layer 23, may be formed on an upper surface of the case body 50. The case body 50 may be formed of any synthetic resin material and, in more detail, a material such as polycarbonate (PC), polyethylene terephthalate (PET), or polypropylene (PP).

According to an embodiment of the present invention, the portable electronic device case 1 may be manufactured as follows:

Specifically, the manufacturing of the portable electronic device case 1 includes adhesive applying in operation S100 or S100′, reinforcing strengthener attaching in operation S200 or S200′, elastic layer forming in operation S300 or S300′, surface polishing in operation S400 or S400′. and injection molding in operation S600 or S600′, as shown in FIGS. 5 and 6.

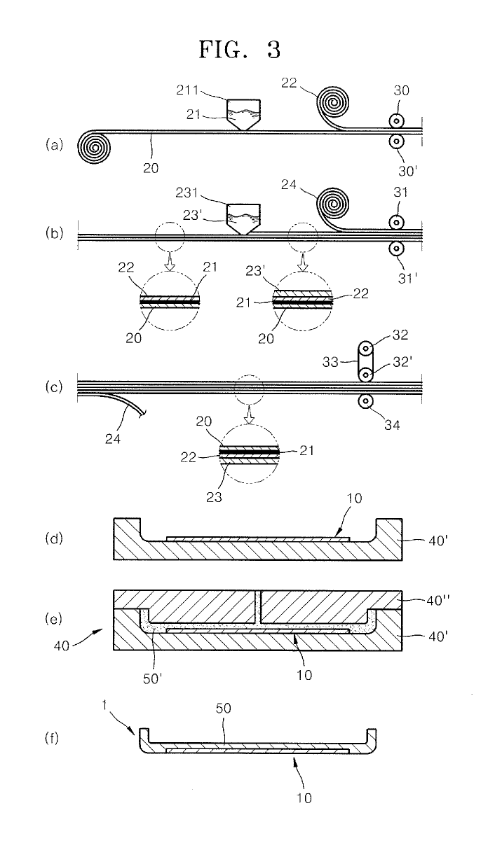

With regard to the adhesive applying in operation S100 or S100′, the adhesive 21 is applied to a back side of the sliced veneer sheet 20. As shown in FIG. 3A, the sliced veneer sheet 20 that is wound in the form of a roll, is moved in one direction, and thus passes through a certain container 211. Thus, the adhesive 21, discharged from the container 211, is applied to one side of the sliced veneer sheet 20. However, a method of applying the adhesive 21 to the sliced veneer sheet 20 is not limited thereto. The adhesive 21 may be applied by using a spraying method or other various methods.

With regard to the reinforcing strengthener attaching in operation S200 or S200′, the reinforcing strengthener 22 is attached to the sliced veneer sheet 20 of which one side is applied with the adhesive 21. In detail, the reinforcing strengthener 22, which has a higher tensile and rupture strength than the sliced veneer sheet 20, is attached to a back side of the sliced veneer sheet 20, so as to reinforce a strength of the sliced veneer sheet 20. As such, the sliced veneer sheet 20, to which is the reinforcing strengthener 22 is attached, may be protected from being cracked or stripped. Additionally, later in a process of injection molding, while a synthetic resin material in a high-temperature melting state is filled in a mold 40, the reinforcing strengthener 22 may prevent the synthetic resin material in a high-temperature melting state from penetrating into the reinforcing strengthener 22 and flowing into the sliced veneer sheet 20. With regard to the reinforcing strengthener attaching in operation S200 or S200′, a certain roller 30 or 30′ may be used to firmly attach the reinforcing strengthener 22 to a back side of the sliced veneer sheet 20.

With regard to the elastic layer forming in operation S300 or S300′, the elastic layer 23 that is made of a more elastic material than the sliced veneer sheet 20 is provided on a surface of the reinforcing strengthener 22, so as to provide elasticity to the sliced veneer sheet 20. The elastic layer 23 may provide elasticity or flexibility to the sliced veneer sheet 20. Thus, the elastic layer 23 may absorb an external shock, and even when the portable electronic device case 1 is excessively bent, the portable electronic device case 1 may endure, and not be damaged. The elastic layer forming in operation S300 or S300′ includes applying of an elastic material 23′ to a surface of the reinforcing strengthener 22 in operation S310′, attaching a film 24 to the surface of the elastic material 23′ in operation S320′, uniforming a surface of the elastic material 23′ by pressing an entire surface of the film 24 in operation S330′, and removing the film 24 in operation S340′.

In detail, as shown in FIG. 3B, an outlet of a container 231, which contains a liquid elastic material 23′ that forms the elastic layer 23, passes through the sliced veneer sheet 22 to which the reinforcing strengthener 22 is attached. The elastic material 23′ may be applied to a surface of the reinforcing strengthener 22. After the elastic material 23′ is applied to the surface of the reinforcing strengthener 22, the elastic material 23′ is pressed by using a roller 31 or 31′ so that the elastic material 23′ is evenly spread to the elastic material 23′, and thus firmly attached to the reinforcing strengthener 22. In order to prevent a sticky elastic material from sticking to the roller 31 or 31′, an entire surface of the film 24 is pressed in a state that the certain film 24 covers the elastic material 23′. After the elastic material 23′ is evenly applied to the surface of the reinforcing strengthener 22 and hardened, the film 24 is removed from the elastic layer 23. The removing of the film 24 may be performed before the surface polishing in operation S400 or S400′.

With regard to the surface polishing in operation S400 or S400′ shown in FIG. 3C, after the film 24 is removed, in a state that the sliced veneer sheet 20, the reinforcing strengthener 22, and the elastic layer 23 are laminated to each other, a surface of the sliced veneer sheet 20 is polished and, at the same time, a structure in the sliced veneer is softened by using a certain polishing element. The surface polishing in operation S400 or S400′ may reduce a thickness of the sliced veneer so as to maintain a thin thickness of the sliced veneer sheet 20 and, at the same time, may soften a structure in the sliced veneer so that the sliced veneer sheet 20 is smoothed overall.

Since the surface polishing in operation S400 or S400′ is performed in a state that the reinforcing strengthener 22 and the elastic layer 23 are attached to the sliced veneer sheet 20, the sliced veneer sheet 20 may be prevented from being damaged in a process of the surface polishing in operation S400 or S400′. The surface polishing in operation S400 or S400′ is performed by using a pair of rollers 32 and 32′ that extend in a vertical direction, a polishing sheet 33 having a curved surface, around which the rollers 32 and 32′ are rolled, and a roller 34 that supports the sliced veneer sheet 20. In other words, while rotating around the rollers 32 and 32′, the polishing sheet 33 polishes a surface of the sliced veneer sheet 20. A vibration, caused by the rotating of the polishing sheet 33, may soften a structure in the sliced veneer sheet 20.

With regard to the injection molding in operation S600 and S600′, the case body 50, which is formed of a synthetic resin material to cover at least one side of the portable electronic device 100, is injection-molded by inserting the sliced veneer assembly 10 that is formed of the sliced veneer sheet 20, the reinforcing strengthener 22, and the elastic layer 23 into the mold 40.

The injection molding is executed, in such a state that the sliced veneer assembly 10 is mounted in a cavity of a lower mold 40′ as shown in FIG. 3D, by covering the cavity using an upper mold 40″ as shown in FIG. 3E, and then, injecting a synthetic resin material 50′ in a melting state under a high pressure through an injection opening that is formed on the upper mold 40″. Injection conditions such as an injection temperature, pressure, and time may vary with a type of a raw material and an adherent material. However, it may be desirable to keep the injection temperature at 110° C. to 200° C., the injection pressure at 5 kg/cm² to 60 kg/cm², and the injection time at 20 to 180 seconds. As the injection object is formed, the sliced veneer assembly 10 becomes one body as the injection object, and thus, becomes a surface of the injection object.

The elastic layer 23, provided on a back side of the reinforcing strengthener 22 in a process of the injection molding, is changed to a melting state together with the injected synthetic resin material. Then, the elastic layer 23 and an injection molding material are mixed with each other, so that the injection molding material may be firmly attached to the sliced veneer sheet 20. Since the reinforcing strengthener 22 is formed of a material which has a higher melting point than the synthetic resin material, the melted synthetic resin material may be prevented from passing through the reinforcing strengthener 22 and flowing into the sliced veneer sheet 20.

After the injection is completed, as shown in FIG. 3F, the portable electronic device case 1 is removed from the mold 40, and thus, is finished.

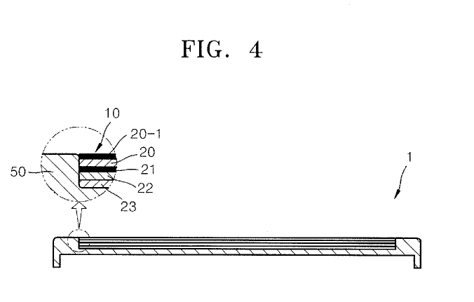

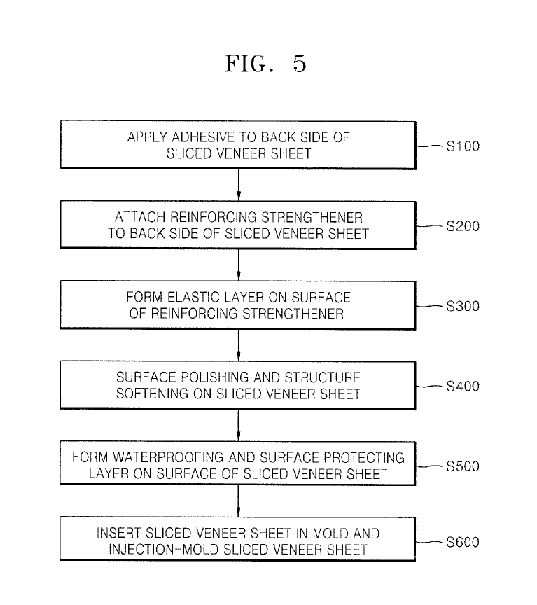

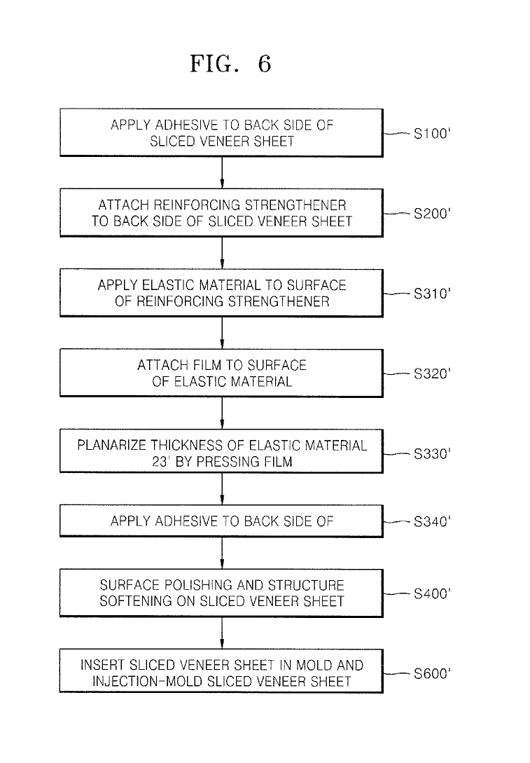

Additionally, according to an embodiment of the present invention, the portable electronic device case 1 may further include a waterproofing and surface protecting layer 20-1 as described below. For example, as shown in FIG. 4, the waterproofing and surface protecting layer 20-1 for maintaining waterproofing performance and protecting a surface of the sliced veneer sheet 20 may be formed on a surface of the sliced veneer sheet 20.

Additionally, in operation S500, waterproofing and surface protecting layer forming for forming the waterproofing and surface protecting layer 20-1 on a surface of the sliced veneer sheet 20 is further included between the elastic layer forming in operation S300 or S300′ and the injection molding in operation S600 and S600′ in the method of manufacturing the portable electronic device case 1, so as to maintain waterproofing performance at and protect the surface of the sliced veneer sheet 20 by filling a void on the surface of the sliced veneer sheet 20. The waterproofing and surface protecting layer 20-1 may be formed of a material such as polyurethane, polyester, or PET. The waterproofing and surface protecting layer 20-1 may be formed by using a painting method, or by molding a waterproofing and surface protecting sheet (not illustrated) to conform to the sliced veneer sheet 20 as one body in a process of the injection molding. For example, a method of using the waterproofing and surface protecting sheet is as follows: First, the waterproofing and surface protecting sheet is inserted with the sliced veneer sheet 20 into the mold 40, so that the waterproofing and surface protecting sheet may contact an inner surface of the mold 40. Then, when the mold 40 is in a high-temperature state, the waterproofing and surface protecting sheet, in contact with the inner surface of the mold 40, melts or remains, and thus, a certain waterproofing and surface protection layer 20-1 may be formed on a surface of the sliced veneer sheet 20.

According to an embodiment of the present invention, a portable electronic device case is provided with a sliced veneer sheet, so that the portable electronic device case 1 may have an aesthetic and beautiful look.

Additionally, a reinforcing strengthener is provided on a back side of the sliced veneer sheet, thus preventing stripping, deformation, or damage of the sliced veneer, which may be caused by a long-time exposure to the outside.

As an elastic layer is formed on a surface of the reinforcing strengthener, an adhesive force between the reinforcing strengthener and a synthetic resin material that forms a case body may be increased. Additionally, the elastic layer may have such a ratio of expansion and contraction that an external shock may be absorbed, and a split in the sliced veneer sheet, which may be caused by moisture or heat, may be prevented.

Additionally, a waterproofing and surface protecting layer is formed on a surface of the sliced veneer. Thus, external moisture may be prevented from penetrating into the sliced veneer sheet.

While this invention has been particularly shown and described with reference to preferred embodiments thereof, it will be understood by those skilled in the art that various changes in form and details may be made therein without departing from the spirit and scope of the invention as defined by the appended claims.

1. A method for manufacturing a case for a portable electronic device, the method comprising:
adhesive applying for applying an adhesive to a back side of a sliced veneer sheet;
reinforcing strengthener attaching for attaching a reinforcing strengthener, which has a higher tensile and rupture strength than the sliced veneer sheet, to the back side of the sliced veneer sheet, so as to reinforce a strength of a sliced veneer;
elastic layer forming for providing an elastic layer, which is made of a more elastic material than the sliced veneer sheet, to a surface of the reinforcing strengthener so as to provide elasticity to the sliced veneer sheet; and
injection molding for injection-molding a case body that is formed of a synthetic resin material to cover at least one side of the portable electronic device, by inserting the sliced veneer sheet, the reinforcing strengthener, and the elastic layer into a mold.

2. The method of claim 1, further comprising, between the elastic layer forming and the injection molding, surface polishing for polishing a surface of the sliced veneer sheet and, at the same time, softening a structure in the sliced veneer by using a certain polishing element.

3. The method of claim 1, wherein the elastic layer forming comprises:
applying of an elastic material to a surface of the reinforcing strengthener;
attaching a film to the surface of the elastic material;
uniforming a thickness of the elastic material by pressing an entire surface of the film; and
removing the film.

4. The method of claim 1, further comprising, between the elastic layer forming and the injection molding, waterproofing and surface protecting layer forming for forming a waterproofing and surface protecting layer on a surface of the sliced veneer sheet, so as to maintain waterproofing performance at and protect the surface of the sliced veneer sheet.

5. The method of claim 4, wherein the waterproofing and surface protecting layer forming is performed when, in such a state that a waterproofing and surface protecting sheet is formed to face the sliced veneer sheet and inserted together with the sliced veneer sheet into the mold, the waterproofing and surface protecting sheet melts or remains in a process of the injection molding, and thus, the waterproofing and surface protecting layer is formed on a surface of the sliced veneer sheet.

6. The method of claim 1, wherein the reinforcing strengthener is formed of a material that has a higher melting point than a synthetic resin material, which forms the case body, and prevents a synthetic resin material in a melting state from penetrating into the sliced veneer sheet in a process of the injection molding, wherein the reinforcing strengthener is formed of non-woven fabric or other clothes.

7. The method of claim 1, wherein the elastic layer is formed of one from among polyvinyl acetate, polyurethane, rubber and silicon.

8. A case for a portable electronic device, the case comprising:
a sliced veneer sheet;
a reinforcing strengthener, which has a higher tensile and rupture strength than the sliced veneer sheet, a the back side of the sliced veneer sheet, so as to reinforce a strength of the sliced veneer sheet;
an elastic layer, which is made of a more elastic material than the sliced veneer sheet and formed on a surface of the reinforcing strengthener, so as to provide elasticity to the sliced veneer sheet; and
a case body formed of a synthetic material, which is injection-molded by inserting the sliced veneer sheet, the reinforcing strengthener, and the elastic layer into the mold, wherein the case body is detachably attached to the portable electronic device to support the sliced veneer sheet, the reinforcing strengthener, and the elastic layer and have a form to cover at least one side of the portable electronic device.

9. The case of claim 8, wherein the reinforcing strengthener is formed of a material that has a higher melting point than a synthetic resin material, which forms the case body, wherein the reinforcing strengthener is formed of non-woven fabric or other clothes.

10. The case of claim 8, wherein the elastic layer is formed of one from among polyvinyl acetate, polyurethane, rubber and silicon.

11. The case of claim 8, wherein a waterproofing and surface protecting layer is formed on a surface of the sliced veneer sheet, so as to maintain waterproofing performance and protect the surface of the sliced veneer sheet.
